(19) United States
(12) Patent Application Publication
(10) Pub. No.: US 2025/0219018 A1
(43) Pub. Date: Jul. 3, 2025

(54) SEMICONDUCTOR PACKAGING METHOD, SEMICONDUCTOR ASSEMBLY COMPONENT AND ELECTRONIC DEVICE

(71) Applicant: Yibu Semiconductor Co., Ltd., Shanghai (CN)

(72) Inventor: Yifan Guo, Shanghai (CN)

(73) Assignee: Yibu Semiconductor Co., Ltd., Shanghai (CN)

(21) Appl. No.: 19/004,312

(22) Filed: Dec. 28, 2024

(30) Foreign Application Priority Data
Dec. 28, 2023 (CN) 202311850184.6

(51) Int. Cl. H01L 23/00; H01L 21/48; H01L 21/56; H01L 25/00

(52) U.S. Cl. CPC H01L 24/81; H01L 21/4846; H01L 25/50; H01L 21/56; H01L 2224/81005; H01L 2224/81035; H01L 2224/81132; H01L 2224/81895

(57) ABSTRACT

Disclosed are a semiconductor packaging method, a semiconductor component and an electronic device. The semiconductor packaging method comprises: forming first alignment bonding parts at first target positions on a carrier, and attaching interconnection devices to second target positions of the carrier, each of the interconnection devices having second alignment bonding parts formed on a side of the interconnection device facing away from the carrier. The method further comprises: aligning and connecting a portion of the third alignment bonding parts of an active surface of a respective semiconductor device with corresponding ones of the first alignment bonding parts, and aligning and connecting the remaining third alignment bonding parts of the active surface of the respective semiconductor device with corresponding ones of the second alignment bonding parts by fusion bonding. Bonding with the alignment bonding parts prevent the semiconductor device from shifting and rotating in a subsequent molding process, thereby improving the yield of the semiconductor packaging process.

### CROSS REFERENCE TO RELATED APPLICATION

The present application claims the benefit of priority under the Paris Convention to Chinese Patent Application No. 202311850184.6, filed on Dec. 28, 2023, which is incorporated herein by reference in its entirety.

### TECHNICAL FIELD

The disclosure relates to the field of semiconductor technology, and to a semiconductor packaging method, a semiconductor component and an electronic device.

### BACKGROUND

Semiconductor packaging and systems have been pursued to be compact, small, light, thin in design, while realizing more integration and versatility in functional aspects. Various packaging techniques are currently proposed to meet the above requirements, such as Fan-out Wafer Level packaging, Chiplet packaging, heterogeneous integration, 2.5D/3D packaging.

In various semiconductor packaging and system fabricating processes, high-precision placement and position fixation of chips are needed. These process steps are usually performed by a high-precision chip mounter, but the placement speed of a chip mounter machine is slow, resulting in poor production efficiency, high equipment cost and low positioning accuracy. Further, placement of chips mainly depends on the accuracy of the chip mounter, which has become a major bottleneck in the development and popularization of the technology.

### SUMMARY

In order to solve the technical problems, the present disclosure provides a semiconductor packaging method, a semiconductor component and an electronic device.

In the first aspect, the present disclosure provides a semiconductor packaging method, comprising: providing a carrier, and forming first alignment bonding parts at first target positions on a side of the carrier; providing interconnection devices and attaching each respective interconnection device of the interconnection devices to a respective second target position of second target positions of the carrier, where the interconnection devices and the first alignment bonding parts are located on the same side of the carrier, and second alignment bonding parts are provided on a side of the respective interconnection device away from the carrier; and providing semiconductor devices, where an active surface of each respective semiconductor device of the semiconductor devices is provided with third alignment bonding parts, aligning and connecting a portion of the third alignment bonding parts with the first alignment bonding parts by fusion bonding, and aligning and connecting the remaining third alignment bonding parts with the second alignment bonding parts. Each of the first alignment bonding parts includes one of an alignment solder bump and an alignment bonding pad, and the third alignment bonding part corresponding to the first alignment bonding part includes the other one of the alignment solder bump and the alignment bonding pad. Each of the second alignment bonding parts includes one of an alignment solder bump and an alignment bonding pad, and the third alignment bonding part corresponding to the second alignment bonding part includes the other one of the alignment solder bump and the alignment bonding pad.

In some embodiments, aligning the portion of the third alignment bonding parts with the first alignment bonding parts and aligning the remaining third alignment bonding parts with the second alignment bonding parts by fusion bonding includes: heating the alignment solder bumps, so that the alignment solder bumps are at least partially in a molten state; and bonding the alignment solder bumps at least partially in the molten state with first alignment bonding pads.

In some embodiments, the first alignment bonding parts include first alignment solder bumps and a first redistribution layer, and fourth alignment bonding parts are provided on a side of the respective interconnection device away from the second alignment bonding parts. Forming first alignment bonding parts at first target positions on a side of the carrier includes: forming the first redistribution layer on the side of the carrier; and forming the first alignment solder bumps at the first target positions on a side of the first redistribution layer away from the carrier. Attaching each respective interconnection device of the interconnection devices to each respective second target position of second target positions of the carrier includes: etching the first redistribution layer located at the second target positions to form openings, where the carrier is exposed by the openings; forming fifth alignment bonding parts on a side of the carrier exposed by the openings; and aligning and connecting the fifth alignment bonding parts with the fourth alignment bonding parts by fusion bonding. One of the fourth alignment bonding parts and the fifth alignment bonding parts are the alignment solder bumps, and the other of the fourth alignment bonding parts and the fifth alignment bonding parts are the alignment bonding pads.

In some embodiments, the first alignment bonding parts include first alignment solder bumps and a first redistribution layer, and fourth alignment bonding parts are provided on a side of the respective interconnection device away from the second alignment bonding parts. Forming the first alignment bonding parts at first target positions on the side of the carrier include: forming the first redistribution layer on the side of the carrier; and forming the first alignment solder bumps at the first target positions on a side of the first redistribution layer away from the carrier. Attaching each respective interconnection device of the interconnection devices to each respective target position of second target positions of the carrier includes: forming fifth alignment bonding parts at the second target positions on the side of the first redistribution layer away from the carrier; and aligning and connecting the fifth alignment bonding parts with the fourth alignment bonding parts by fusion bonding. One of the fourth alignment bonding parts and the fifth alignment bonding parts are the alignment solder bumps, and the other of the fourth alignment bonding parts and the fifth alignment bonding parts are the alignment bonding pads.

In some embodiments, the first alignment bonding parts include first alignment solder bumps, a first redistribution layer, and a second redistribution layer, and fourth alignment bonding parts are provided on a side of the respective interconnection device away from the second alignment bonding parts. Forming first alignment bonding parts at first target positions on a side of the carrier include: forming the second redistribution layer on the side of the carrier; forming the first redistribution layer on a side of the second redistribution layer away from the carrier; and forming the first alignment solder bumps at the first target positions on a side of the first redistribution layer away from the second redistribution layer. Attaching each respective interconnection device of the interconnection devices to each respective second target position of second target positions of the carrier includes: etching the first redistribution layer at the second target positions to form openings, where the second redistribution layer is exposed by the openings; forming fifth alignment bonding parts on a side of the second redistribution layer exposed by the openings; and aligning and connecting the fifth alignment bonding parts with the fourth alignment bonding parts by fusion bonding. One of the fourth alignment bonding parts and the sixth alignment bonding parts are the alignment solder bumps, and the other of the fourth alignment bonding parts and the sixth alignment bonding parts are the alignment bonding pads.

In some embodiments, the first alignment bonding parts include first alignment solder bumps and third alignment bonding pads, and fourth alignment solder bumps are provided on a side of the respective interconnection device away from the second alignment bonding parts. Forming first alignment bonding parts at first target positions on a side of the carrier includes: forming a metal layer on the side of the carrier; etching the metal layer, and forming the third alignment bonding pads at the first target positions and the second target positions; and forming the first alignment solder bumps at the first target positions on a side of the third alignment bonding pads away from the carrier. Attaching each respective interconnection device of the interconnection devices to a respective second target position of second target positions of the carrier includes: aligning and connecting the fourth alignment solder bumps with the third alignment bonding pads located at the second target positions by fusion bonding.

In some embodiments, the second alignment bonding parts include second alignment solder bumps, and the third alignment bonding parts include first alignment bonding pads. Aligning a portion of the third alignment bonding parts with the first alignment bonding parts and aligning the remaining third alignment bonding parts with the second alignment bonding parts by fusion bonding includes: aligning and connecting a portion of the first alignment bonding pads with the first alignment solder bumps by fusion bonding, and aligning and connecting the remaining first alignment bonding pads with the second alignment solder bumps.

In some embodiments, the second alignment bonding parts include second alignment bonding pads, and the third alignment bonding parts include first alignment bonding pads and third alignment solder bumps. Aligning a portion of the third alignment bonding parts with the first alignment bonding parts and aligning the remaining third alignment bonding parts with the second alignment bonding parts by fusion bonding includes: aligning and connecting a portion of the first alignment bonding pads with the first alignment solder bumps and aligning and connecting the third alignment solder bumps with the second alignment bonding pads by fusion bonding.

In some embodiments, the first alignment bonding parts include third alignment bonding pads, and fourth alignment solder bumps are provided on a side of the respective interconnection device away from the second alignment bonding parts. Forming first alignment bonding parts at first target positions on a side of the carrier includes: forming the third alignment bonding pads at the first target positions and the second target positions on the side of the carrier. Attaching each respective interconnection device of the interconnection devices to a respective second target position of second target positions of the carrier includes: aligning and connecting the fourth alignment solder bumps with the third alignment bonding pads located at the second target positions by fusion bonding.

In some embodiments, the second alignment bonding parts include second alignment bonding pads, and the third alignment bonding parts includes third alignment solder bumps and fifth alignment solder bumps. Aligning a portion of the third alignment bonding parts with the first alignment bonding parts and aligning the remaining third alignment bonding parts with the second alignment bonding parts by fusion bonding includes: aligning and connecting the fifth alignment solder bumps with the third alignment bonding pads, and aligning and connecting the third alignment solder bumps with the second alignment bonding pads by fusion bonding.

In some embodiments, the second alignment bonding parts include second alignment solder bumps, and the third alignment bonding parts include fifth alignment solder bumps and first alignment bonding pads. Aligning a portion of the third alignment bonding parts with the first alignment bonding parts and aligning the remaining third alignment bonding parts with the second alignment bonding parts by fusion bonding includes: aligning and connecting the fifth alignment solder bumps with the third alignment bonding pads, and aligning and connecting the first alignment bonding pads with the second alignment solder bumps by fusion bonding.

In some embodiments, the second alignment bonding parts include thermo-compression bonding pads having a solder mask, and the third alignment bonding parts include fifth alignment solder bumps and first alignment bonding pads. Aligning a portion of the third alignment bonding parts with the first alignment bonding parts and aligning the remaining third alignment bonding parts with the second alignment bonding parts by fusion bonding includes: aligning and connecting the fifth alignment solder bumps with the third alignment bonding pads by fusion bonding; and aligning and connecting the first alignment bonding pads and the thermo-compression bonding pads by thermo-compression bonding.

In some embodiments, the semiconductor packaging method further includes: forming a molding layer, where the semiconductor devices, the interconnection devices and the first alignment bonding parts are wrapped by the molding layer; removing the carrier; forming a third redistribution layer on a side of the molding layer away from the semiconductor device; and forming a connection structure on a side of the third redistribution layer away from the molding layer, where the connection structure is electrically connected with the third redistribution layer.

In the second aspect, the embodiments of the present disclosure also provide a semiconductor component by packaging based on any one of the above semiconductor packaging methods.

In the third aspect, the embodiments of the present disclosure also provide an electronic device, which includes the above-mentioned semiconductor component.

Compared with the existing technology, the technical scheme provided by the disclosure has the following advantages.

The embodiments of the present disclosure provide a semiconductor packaging method, a semiconductor component and an electronic device, in the semiconductor packaging method: forming the first alignment bonding parts at the first target positions of the carrier, fixing the respective interconnection device at the respective second target positions of the carrier, providing the second alignment bonding parts on the side of the respective interconnection device away from the carrier, aligning and connecting the portion of the third alignment bonding parts of the active surface of the semiconductor device with the first alignment bonding parts and the second alignment bonding parts by fusion bonding, the first alignment bonding parts include one of the alignment solder bumps and the alignment bonding pads, the third alignment bonding parts corresponding to the first alignment bonding parts include the other of the alignment solder bumps and the alignment bonding pads, the second alignment bonding parts include one of the alignment solder bumps and the alignment bonding pads, and the third alignment bonding parts corresponding to the second alignment bonding parts include the other of the alignment solder bumps and the alignment bonding pads. Therefore, when the alignment solder bumps and the alignment bonding pads are bonded in a fusion mode, the alignment bonding pads are automatically pulled to target positions by surface tension generated by the alignment solder bumps in a fusion state based on the minimum surface energy principle, thereby realizing automatic alignment of the alignment solder bumps and the alignment bonding pads. Meanwhile, the positions of the first alignment bonding parts and the interconnection devices on the carrier are determined, the semiconductor device is accurately fixed at the target position by alignment bonding parts of the alignment solder bumps and the alignment bonding pads, the alignment solder bumps can prevent the semiconductor device from shifting and rotating in the molding process after cooling down, the yield of the subsequent process can be effectively improved. Further, a certain degree of placement deviation is allowed when the semiconductor device is picked and placed in view of the self-alignment capability of the alignment solder bumps, that is, the requirement on the placement precision of the semiconductor device is reduced, thus the speed of the picking and placement operation of the semiconductor device is improved, thereby improving the process efficiency, and reducing the process cost.

### BRIEF DESCRIPTION OF THE DRAWINGS

The accompanying drawings, which are incorporated in and constitute a part of this specification, illustrate embodiments consistent with the disclosure and together with the description, explain the principles of the present disclosure.

In order to more clearly illustrate the embodiments of the present disclosure or the solutions in the prior technology, the drawings that are required for the description of the embodiments or the prior technology will be briefly described below, and it will be obvious to those skilled in technology that other drawings can be obtained from these drawings without inventive efforts.

FIG. 1 is a schematic flowchart of a semiconductor packaging method according to an embodiment of the disclosure.

FIG. 2 is a schematic structural diagram of steps of a semiconductor packaging method according to an embodiment of the disclosure.

FIG. 3 is a schematic structural diagram of steps of another semiconductor packaging method according to an embodiment of the present disclosure.

FIG. 4 is a schematic structural diagram of steps of another semiconductor packaging method according to an embodiment of the present disclosure.

FIG. 5 is a schematic structural diagram of steps of another semiconductor packaging method according to an embodiment of the present disclosure.

FIG. 6 is a schematic structural diagram of steps of another semiconductor packaging method according to an embodiment of the present disclosure.

FIG. 7 is a schematic structural diagram of a semiconductor device according to an embodiment of the present disclosure.

FIG. 8 is a schematic structural diagram of another semiconductor device according to an embodiment of the present disclosure.

FIG. 9 is a schematic structural diagram of another semiconductor device according to an embodiment of the present disclosure.

FIG. 10 is a schematic structural diagram of another semiconductor device according to an embodiment of the present disclosure.

FIG. 11 is a schematic structural diagram of another semiconductor device according to an embodiment of the present disclosure.

FIG. 12 is a schematic structural diagram of another semiconductor device according to an embodiment of the present disclosure.

FIG. 13 is a schematic structural diagram of another semiconductor device according to an embodiment of the present disclosure.

FIG. 14 is a schematic structural diagram of another semiconductor device according to an embodiment of the present disclosure.

FIG. 15 is a schematic structural diagram of steps of another semiconductor packaging method according to an embodiment of the present disclosure.

FIG. 16 is a schematic structural diagram of another semiconductor device according to an embodiment of the present disclosure.

FIG. 17 is a schematic flowchart illustrating another semiconductor packaging method according to an embodiment of the present disclosure.

### DETAILED DESCRIPTION OF THE EMBODIMENTS

In order that the above objects, features and advantages of the present disclosure may be more clearly understood, further description of aspects of the present disclosure will be provided below. It should be noted that, without conflict, the embodiments of the present disclosure and features in the embodiments may be combined with each other.

In the following description, numerous specific details are set forth to provide a thorough understanding of the present disclosure, but the present disclosure may be practiced otherwise than as described herein. It will be obvious that the embodiments in the specification are only some, but not all, embodiments of the present disclosure.

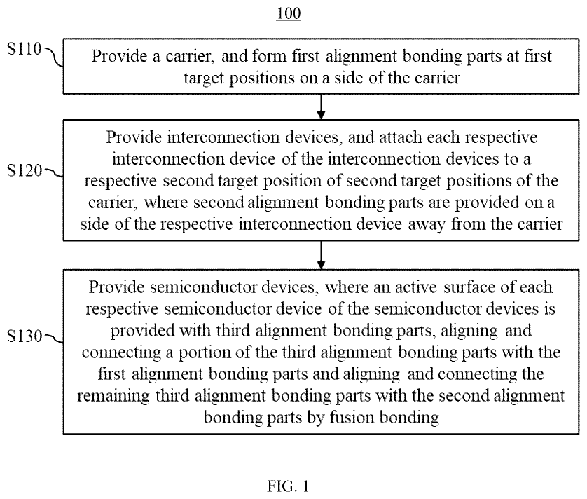

In some embodiments, as shown in FIG. 1, a semiconductor packaging method 100 includes steps S110, S120 and S130, as described in further details below with reference to FIGS. 1-5.

At S110, a carrier 8 is provided, and first alignment bonding parts are formed at first target positions on a side of the carrier.

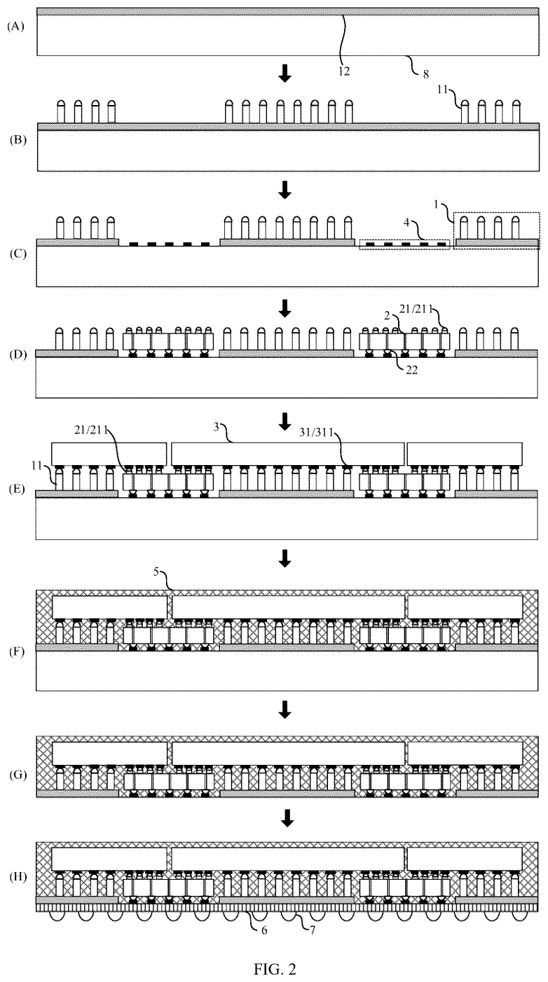

Referring to FIG. 2 to FIG. 5, the type of the carrier 8 is not limited by the embodiment of the present disclosure, and any type of carrier known to those skilled in technology may be used, for example, the carrier 8 includes at least one of a glass carrier, a ceramic carrier, a metal carrier, an organic polymer material carrier, and a silicon wafer.

In this step, a two-dimensional coordinate system (X, Y) is established on the plane of the carrier 8, and the first alignment bonding parts 1 are formed at the first target positions in the two-dimensional coordinate system (X, Y), where the first alignment bonding parts 1 are used for alignment bonding with a portion of the third alignment bonding parts 31 located on the active surface of the semiconductor device 3 in a subsequent step.

At S120, interconnection devices are provided, and the interconnection devices are attached to second target positions in the two-dimensional coordinate system (X, Y) established on the plane of the carrier, where second alignment bonding parts are arranged on a side of the interconnection device away from the carrier.

The type of the interconnection device 2 is not limited by the embodiment of the present disclosure, and any device or structure having an interconnection function, such as a silicon bridge or a structure having a conductive wire layer provided on one side surface, which is known to those skilled in art, may be used. The interconnection device 2 realizes electrical connection between the semiconductor devices 3.

In this step, in combination with FIG. 2 to FIG. 5, the interconnection devices 2 are accurately fixed on the carrier at the second target positions, the interconnection devices 2 and the first alignment bonding parts 1 are located on the same side of the carrier 8, the second alignment bonding parts 21 are provided on the side of the interconnection device 2 away from the carrier 8, and the second alignment bonding parts 21 are used for aligning and connecting with the remaining third alignment bonding parts 31 located on the active surface of the semiconductor device 3 in the subsequent step.

Fourth alignment bonding parts 22 are provided on a side of the interconnection devices 2 away from the second alignment bonding parts 21, and fifth alignment bonding parts 4 corresponding to the fourth alignment bonding parts 22 are formed at the second target positions of the carrier 8. The fourth alignment bonding parts 22 are alignment solder bumps, while the fifth alignment bonding parts 4 are alignment bonding pads. Or, the fifth alignment bonding parts 4 are alignment solder bumps, while the fourth alignment bonding parts 22 are alignment bonding pads. The interconnection devices 2 are accurately fixed at the second target positions of the carrier by aligning and connecting the fourth alignment bonding parts 22 with respective ones of the fifth alignment bonding parts 4.

In other embodiments, the interconnection devices 2 may also be fixed to the carrier 8 by means of a bonding layer on a side of the interconnection device 2 away from the second alignment bonding parts 21, which is not limited herein. In some embodiments, the first alignment bonding parts 1 and the interconnect device are not embedded or partially embedded in a molding layer before S130 is performed. In other words, no molding process is performed before S130.

At S130, semiconductor devices are provided, where an active surface of each respective semiconductor device of the semiconductor devices is provided with third alignment bonding parts, a portion of the third alignment bonding parts are aligned and connected with the first alignment bonding parts by fusion bonding, and the remaining third alignment bonding parts are aligned and connected with the second alignment bonding parts.

In this embodiment, the semiconductor device 3 includes, but is not limited to, a die, a chip, a High Bandwidth Memory (HBM), a System-on-a-Chip (SOC), an Application Specific Integrated Circuit (ASIC), and a Programmable Logic Device (PLD). The semiconductor device 3 includes an active surface and a passive surface which are oppositely arranged, and the active surface includes third alignment bonding parts 31.

In this embodiment, the first alignment bonding parts 1 include alignment solder bumps, while the third alignment bonding parts 31 corresponding to the first alignment bonding parts 1 include alignment bonding pads, or the other way around, i.e., the first alignment bonding parts 1 include alignment bonding pads, while the third alignment bonding parts 31 corresponding to the first alignment bonding parts 1 include alignment solder bumps. Similarly, the second alignment bonding parts 21 include alignment solder bumps, while the third alignment bonding parts 31 corresponding to the second alignment bonding parts 21 include alignment bonding pads, or the other way around, i.e., the second alignment bonding parts 21 include alignment bonding pads, while the third alignment bonding parts 31 corresponding to the second alignment bonding parts 21 include alignment solder bumps.

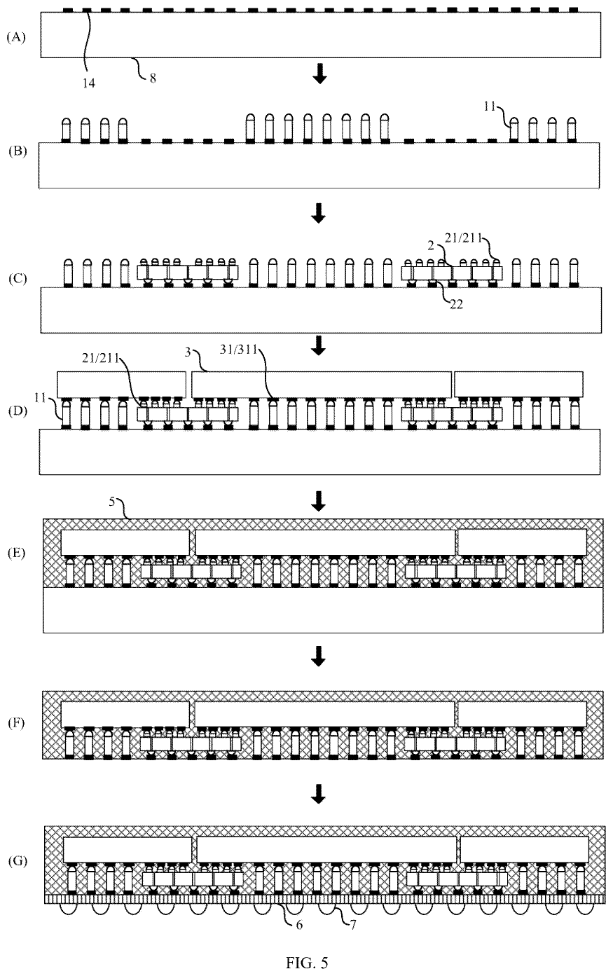

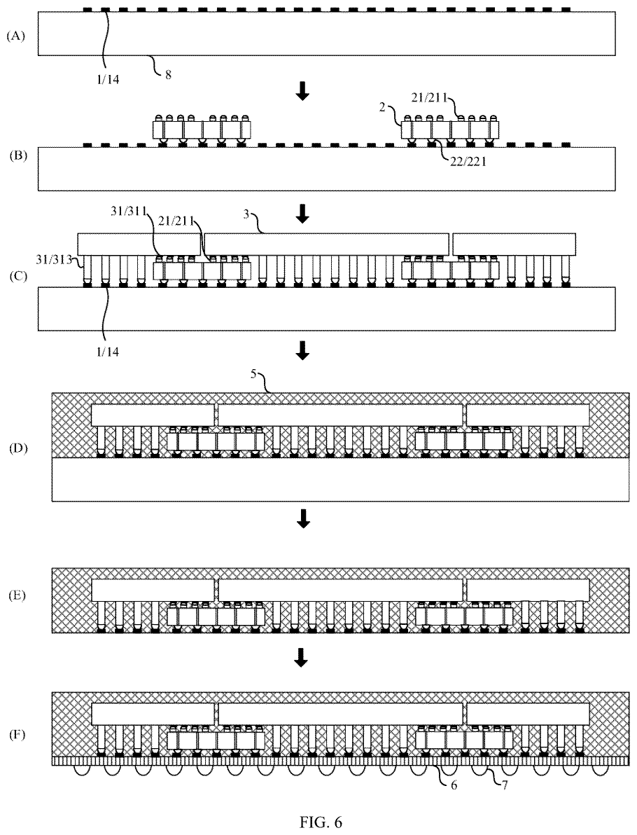

In some embodiments, if the first alignment bonding parts 1 and the second alignment bonding parts 21 are both alignment solder bumps, the third alignment bonding parts 31 are alignment bonding pads (as shown in FIGS. 2 to 4). If the first alignment bonding parts 1 and the second alignment bonding parts 21 are both alignment bonding pads, and the third alignment bonding parts 31 are alignment solder bumps (as shown in FIG. 9). Or, if the first alignment bonding parts 1 are alignment solder bumps and the second alignment bonding parts 21 are alignment bonding pads, the third alignment bonding parts 31 corresponding to the first alignment bonding parts 1 are alignment bonding pads and the third alignment bonding parts 31 corresponding to the second alignment bonding parts 21 are alignment solder bumps (as shown in FIGS. 6 to 8). If the first alignment bonding parts 1 are alignment bonding pads and the second alignment bonding parts 21 are alignment solder bumps, the third alignment bonding parts 31 corresponding to the first alignment bonding parts 1 are alignment solder bumps and the third alignment bonding parts 31 corresponding to the second alignment bonding parts 21 are alignment bonding pads (as shown in FIG. 5).

The alignment solder bumps each include a bump structure formed by solder material. A solder base structure may or may not be included below the bump structure (for example, the alignment solder bumps are solder balls). The solder base structure below the bump structure is not limited by the embodiment of the present disclosure, and the solder base structure may be a pad or a bump. Fusion bonding may be performed by any fusion bonding method known to those skilled in art, including, but not limited to, reflow bonding, laser bonding, high frequency bonding, infrared bonding, and the like.

In this step, as the active surface of the semiconductor device 3 is directed to the first alignment bonding parts 1 and the second alignment bonding parts 21, the portion of the third alignment bonding parts 31 are substantially aligned with the corresponding first alignment bonding parts 1, and the remaining third alignment bonding parts 31 are substantially aligned with the corresponding second alignment bonding parts 21, the third alignment bonding parts 31 and the corresponding first alignment bonding parts 1 (and the third alignment bonding parts 31 and the corresponding second alignment bonding parts 21) are in contact with each other but are not accurately centered in a direction perpendicular to the plane in which the carrier 8 is located. In the bonding process, one of the first alignment bonding parts 1 and the corresponding third alignment bonding parts 31 (and the second alignment bonding parts 21 and the corresponding third alignment bonding parts 31) serving as alignment solder bumps are melted or partially melted to infiltrate the other serving as the alignment bonding pads, and at the moment, based on the minimum surface energy principle, the alignment solder bumps in a molten or partially molten state tend to deform and move to enable the first alignment bonding parts 1 and the third alignment bonding parts 31 (and to enable the second alignment bonding parts 21 and the third alignment bonding parts 31) to approach to a centered state. Thus, the lighter semiconductor device 3 is driven to be accurately aligned to a target position, and the semiconductor device 3 is accurately fixed at the target position after the alignment solder bumps are cooled. As a result, the high-strength mechanical fixation (up to kilogram force level) of the semiconductor device 3 is realized, thereby solving the shift and rotation problems of the semiconductor device 3 in the subsequent molding process, and effectively improving the yield of the subsequent process. Since the positions of the first alignment bonding parts 1 and the interconnection devices 2 on the carrier 8 are determined, the semiconductor device 3 is accurately fixed at the target position on the carrier by controlling the relative position of the semiconductor device 3 and the first alignment bonding parts 1 and the relative positions of the semiconductor device 3 and the interconnection devices 2.

In this context, “substantially aligned” means that the first alignment bonding parts 1 and the third alignment bonding parts 31 (or the second alignment bonding parts 21 and the third alignment bonding parts 31), respectively, are brought in contact with each other, but their positions are exactly centered in a direction perpendicular to the passive surface. “centered” in this context generally means that the centers of the first alignment bonding parts 1 and centers of the third alignment bonding parts 31 are respectively aligned in a direction perpendicular to the platform of the carrier 8. “Accurate alignment” means a state in which a deviation between an actual position of the semiconductor device 3 relative to the carrier 8 and a target position for the semiconductor device 3 is within a tolerance range in art.

It should be noted that FIG. 2 to FIG. 9 only exemplarily illustrate the connection of three semiconductor devices 3 with the first alignment bonding parts 1 and the second alignment bonding parts 21, and do not constitute a limitation of the semiconductor packaging method provided by the embodiment of the present disclosure. In other embodiments, the number of the semiconductor devices 3 may be set as desired, for example, two, four or more, which is not limited herein.

In the semiconductor packaging method provided by the embodiment of the present disclosure, the first alignment bonding parts 1 are formed at the first target positions of the carrier 8, meanwhile, the interconnection devices 2 are fixed at the second target positions of the carrier 8, the second alignment bonding parts 21 are provided on a side of the interconnection device 2 away from the carrier 8, the third alignment bonding parts 31 of the active surface of the semiconductor device 3 are aligned and connected with the first alignment bonding parts 1 and the second alignment bonding parts 21 by fusion bonding, the first alignment bonding parts 1 include one of the alignment solder bumps and the alignment bonding pads, the third alignment bonding parts 31 corresponding to the first alignment bonding parts 1 include the other of the alignment solder bumps and the alignment bonding pads, the second alignment bonding parts 21 include one of the alignment solder bumps and the alignment bonding pads, and the third alignment bonding parts 31 corresponding to the second alignment bonding parts 21 include the other of the alignment solder bumps and the alignment bonding pads. Therefore, when the alignment solder bumps and the alignment bonding pads are bonded in a fusion mode, the alignment bonding pads are automatically pulled to target positions by surface tension generated by the alignment solder bumps in a fusion state based on the minimum surface energy principle, thereby realizing automatic alignment of the alignment solder bumps and the alignment bonding pads. Meanwhile, the positions of the first alignment bonding parts 1 and the interconnection devices 2 on the carrier 8 are determined, the semiconductor device 3 is accurately fixed at a target position by alignment bonding parts of the alignment solder bumps and the alignment bonding pads, the alignment solder bumps can prevent the semiconductor device 3 from shifting and rotating in the molding process after cooling down, the yield of the subsequent process can be effectively improved, a certain degree of placement deviation is allowed when the semiconductor device is picked and placed in view of the self-alignment capability of the alignment solder bumps, that is, the requirement on the placement precision of the semiconductor device is reduced, thus the speed of the picking and placement operation of the semiconductor device is improved, thereby improving the process efficiency, and reducing the process cost.

In some embodiments, the aligning a portion the third alignment bonding parts with the first alignment bonding parts and aligning the remaining third alignment bonding parts with the second alignment bonding parts by fusion bonding includes:
heating the alignment solder bumps, so that the alignment solder bumps are at least partially in a molten state; and
bonding the alignment solder bumps at least partially in the molten state with the first alignment bonding pads.

In this embodiment, the bonding may be performed by any fusion bonding method known to those skilled in art, including, but not limited to, reflow bonding, laser bonding, high frequency bonding, infrared bonding, and the like. The alignment solder bumps are heated to a melting point, a portion of the alignment solder bumps are in a molten state or all of the alignment solder bumps are in a molten state, the alignment solder bumps in the molten state infiltrate the alignment bonding pads, and at this time, based on a minimum surface energy principle, the alignment solder bumps in the molten or partially molten state tend to deform and move to align and connect the first alignment bonding parts 1 with the third alignment bonding parts 31 (and the second alignment bonding parts 21 with the third alignment bonding parts 31), so that the lighter semiconductor device 3 is driven to be accurately aligned to a target position, and the semiconductor device 1 is accurately fixed at the target positions after the alignment solder bumps are cooled.

In some embodiments, as shown in FIG. 2, the first alignment bonding parts 1 include first alignment solder bumps 11 and a first redistribution layer 12. The forming first alignment bonding parts at first target positions on a side of the carrier includes the following steps:
forming the first redistribution layer on the side of the carrier; and
forming the first alignment solder bumps at the first target positions on a side of the first redistribution layer away from the carrier.

In this embodiment, in combination with steps (A)-(B) of FIG. 2, the first redistribution layer 12 is formed on the side of the carrier 8, and then the first alignment solder bumps 11 are formed on the side of the first redistribution layer 12 away from the carrier 8. The first redistribution layer 12 and the first alignment solder bumps 11 are prepared by processes known to those skilled in art, and will not be described herein. The first redistribution layer 12 includes at least one metal layer and at least one insulator layer.

In some embodiments, as shown in FIG. 2, a side of the respective interconnection device 2 away from the second alignment bonding parts 21 is provided with fourth alignment bonding parts 22. The attaching each respective interconnection device of the interconnection devices to each respective target position of second target positions of the carrier includes:
etching the first redistribution layer located at the second target positions to form openings, where the carrier is exposed by the openings;
forming fifth alignment bonding parts in areas on a side of the carrier exposed by the openings; and
aligning and connecting the fifth alignment bonding parts with the fourth alignment bonding parts by fusion bonding;

In this embodiment, one of the fourth alignment bonding parts 22 and the fifth alignment bonding parts 4 are the alignment solder bumps, and the other of the fourth alignment bonding parts and the fifth alignment bonding parts are the alignment bonding pads. In some embodiments, as shown in FIG. 2, the fifth alignment bonding parts 4 are the alignment bonding pads, and the fourth alignment bonding parts 22 are the alignment solder bumps. In some embodiments, as shown in FIG. 12, the fifth alignment bonding parts 4 are the alignment solder bumps, and the fourth alignment bonding parts 22 are the alignment bonding pads.

In this embodiment, in combination with step (C) of FIG. 2, the first redistribution layer 12 is etched by using a dry etching or wet etching process, and openings are formed at the second target positions, where the carrier 8 under the first redistribution layer 12 is exposed by the openings. The fifth alignment bonding parts 4 are then formed on the carrier 8 exposed by the openings using a plating or deposition process, and the fifth alignment bonding parts 4 correspond to the fourth alignment bonding parts 22 on the interconnection device 2.

In connection with step (D) of FIG. 2, a side of the interconnection device 2 having the fourth alignment bonding parts 22 is directed toward the fifth alignment bonding parts 4, and the fourth alignment bonding parts 22 and the fifth alignment bonding parts 4 are in contact with each other without being accurately centered in a direction perpendicular to the plane in which the carrier 8 is located. During the bonding process, one of the fourth alignment bonding parts 22 and the fifth alignment bonding parts 4 serving as alignment solder bumps are melted or partially melted to infiltrate the other of the fourth alignment bonding parts 22 and the fifth alignment bonding parts 4 serving as the alignment solder bumps, and at this time, based on the minimum surface energy principle, the alignment solder bumps in a molten or partially molten state tend to deform and move to bring the fourth alignment bonding parts 22 and the fifth alignment bonding parts 4 near a centered state, thus the lighter interconnection device 2 is driven to be accurately aligned to the second target position, and the interconnection device 2 is accurately fixed at the second target position after the alignment solder bumps are cooled.

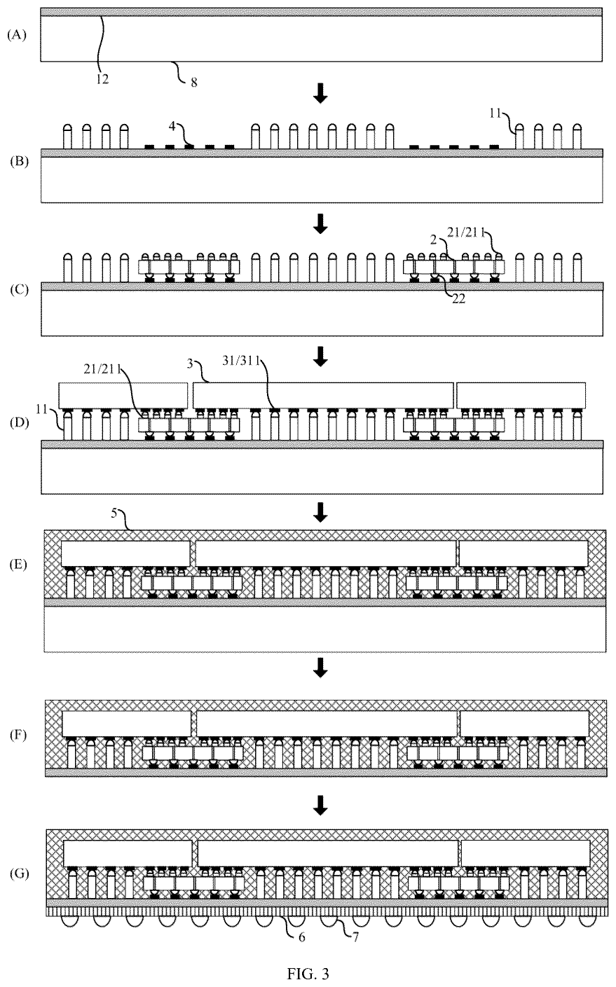

In some embodiments, as shown in FIG. 3, the first alignment bonding parts 1 include first alignment solder bumps 11 and a first redistribution layer 12, and fourth alignment bonding parts 22 are provided on a side of the interconnection device 2 away from the second alignment bonding parts 21. The forming first alignment bonding parts at first target positions on a side of the carrier include:
forming the first redistribution layer on the side of the carrier; and
forming the first alignment solder bumps at the first target positions on a side of the first redistribution layer away from the carrier.

In this embodiment, in combination with steps (A)-(B) of FIG. 3, the first redistribution layer 12 is formed on the side of the carrier 8, and then the first alignment solder bumps 11 are formed on the side of the first redistribution layer 12 away from the carrier 8. The first redistribution layer 12 and the first alignment solder bumps 11 are prepared by processes known to those skilled in art, and will not be described herein. The first redistribution layer 12 includes at least one metal layer and at least one insulator layer.

The attaching each respective interconnection device of the interconnection devices to each respective target position of second target positions of the carrier includes:
forming a fifth alignment bonding parts at a second target positions on one side of the first redistribution layer, which is away from the carrier; and
aligning and connecting the fifth alignment bonding parts with the fourth alignment bonding parts by fusion bonding.

In this embodiment, one of the fourth alignment bonding parts and the fifth alignment bonding parts are the alignment solder bumps, and the other of the fourth alignment bonding parts and the fifth alignment bonding parts are the alignment bonding pads. In some embodiments, as shown in FIG. 3, the fifth alignment bonding parts 4 are the alignment bonding pads, and the fourth alignment bonding parts 22 are the alignment solder bumps. In some embodiments, as shown in FIG. 13, the fifth alignment bonding parts 4 are the alignment solder bumps, and the fourth alignment bonding parts 22 are the alignment bonding pads.

In this embodiment, in combination with step (B) of FIG. 3, the fifth alignment bonding parts 4 are formed on the side of the first redistribution layer 12 away from the carrier 8 by using a plating or deposition process, where the formed fifth alignment bonding parts 4 are located at the second target positions, and the fifth alignment bonding parts 4 correspond to the fourth alignment bonding parts 22 on the interconnection device 2.

In connection with step (C) of FIG. 3, a side of the interconnection device 2 having the fourth alignment bonding parts 22 is directed toward the fifth alignment bonding parts 4, and the fourth alignment bonding parts 22 and the fifth alignment bonding parts 4 are in contact with each other without being accurately centered in a direction perpendicular to the plane in which the carrier 8 is located. During the bonding process, one of the fourth alignment bonding parts 22 and the fifth alignment bonding parts 4 serving as alignment solder bumps are melted or partially melted to infiltrate the other serving as the alignment solder bumps, and at this time, based on the minimum surface energy principle, the alignment solder bumps in a molten or partially molten state tend to deform and move to bring the fourth alignment bonding parts 22 and the fifth alignment bonding parts 4 near a centered state, thus the lighter interconnection device 2 is driven to be accurately aligned to the second target position, and the interconnection device 2 is accurately fixed at the second target position after the alignment solder bumps are cooled.

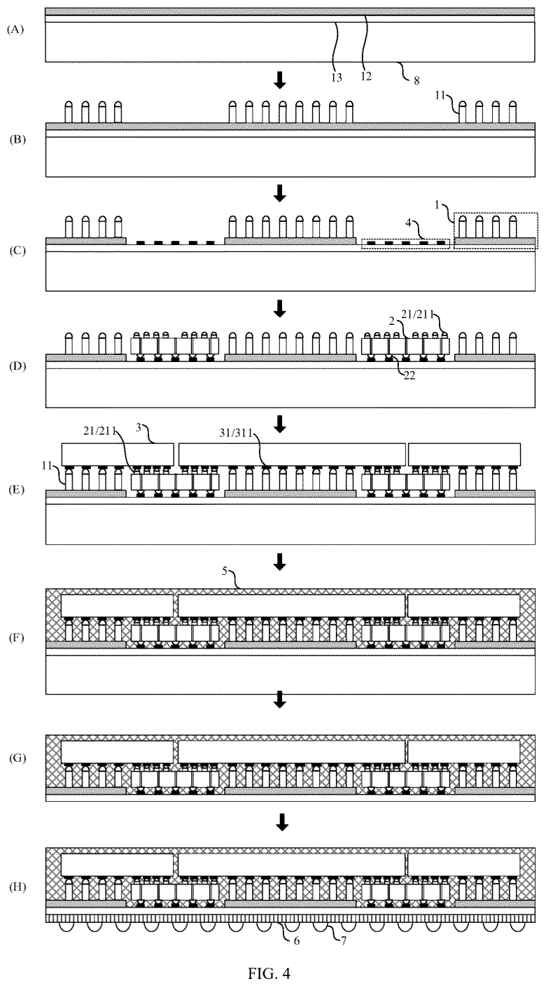

In some embodiments, as shown in FIG. 4, the first alignment bonding parts 1 include first alignment solder bumps 11, a first redistribution layer 12, and a second redistribution layer 13, and fourth alignment bonding parts 22 are provided on a side of the interconnection device 2 away from the second alignment bonding parts 21. The forming first alignment bonding parts at first target positions on a side of the carrier include:
forming the second redistribution layer on the side of the carrier,
forming the first redistribution layer on a side of the second redistribution layer, away from the carrier; and
forming the first alignment solder bumps at the first target positions on a side of the first redistribution layer away from the second redistribution layer.

In this embodiment, in combination with steps (A)-(B) of FIG. 3, the second redistribution layer 13 is formed on the side of the carrier 8, the first redistribution layer 12 is formed on the side of the second redistribution layer 13 away from the carrier 8, and then the first alignment solder bumps 11 are formed on the side of the first redistribution layer 12 away from the second redistribution layer 13. The first redistribution layer 12, the second redistribution layer 13 and the first alignment solder bumps 11 are prepared by processes known to those skilled in art, and will not be described herein. The first and second redistribution layers 12 and 13 each include at least one metal layer and at least one insulator layer. The number of metal layers in the first redistribution layer 12 may or may not be equal to the number of metal layers in the second redistribution layer 13.

The attaching each respective interconnection device of the interconnection devices to each respective target position of second target positions of the carrier includes:
etching the first redistribution layer at the second target positions to form openings, where portions or areas of the second redistribution layer is exposed by the openings;
forming fifth alignment bonding parts on portions or areas of the second redistribution layer exposed by the openings; and;
aligning and connecting the fifth alignment bonding parts with the fourth alignment bonding parts by fusion bonding.

In this embodiment, one of the fourth alignment bonding parts and the sixth alignment bonding parts are the alignment solder bumps, and the other of the fourth alignment bonding parts and the sixth alignment bonding parts are the alignment bonding pads. In some embodiments, as shown in FIG. 4, the fifth alignment bonding parts 4 are the alignment bonding pads, and the fourth alignment bonding parts 22 are the alignment solder bumps. In some embodiments, as shown in FIG. 14, the fifth alignment bonding parts 4 are the alignment solder bumps, and the fourth alignment bonding parts 22 are the alignment bonding pads.

In this embodiment, in combination with step (C) of FIG. 4, the first redistribution layer 12 is etched by using a dry etching or wet etching process, and openings are formed at the second target positions, where the second redistribution layer 13 under the first redistribution layer 12 is exposed by the openings. The fifth alignment bonding parts 4 are then formed on the second redistribution layer 13 exposed by the openings by using a plating or deposition process, and the fifth alignment bonding parts 4 correspond to the fourth alignment bonding parts 22 on the interconnection device 2.

In connection with step (D) of FIG. 4, a side of the interconnection device 2 having the fourth alignment bonding parts 22 is directed toward the fifth alignment bonding parts 4, and the fourth alignment bonding parts 22 and the fifth alignment bonding parts 4 are in contact with each other without being accurately centered in a direction perpendicular to the plane in which the carrier 8 is located, During the bonding process, one of the fourth alignment bonding parts 22 and the fifth alignment bonding parts 4 serving as alignment solder bumps are melted or partially melted to infiltrate the other serving as the alignment solder bumps, and at this time, based on the minimum surface energy principle, the alignment solder bumps in a molten or partially molten state tend to deform and move to bring the fourth alignment bonding parts 22 and the fifth alignment bonding parts 4 near a centered state, thus the lighter interconnection device 2 is driven to be accurately aligned to the second target position, and the interconnection device 2 is accurately fixed at the second target position after the alignment solder bumps are cooled.

In some embodiments, as shown in FIG. 5, the first alignment bonding parts 1 include first alignment solder bumps 11 and third alignment bonding pads 14, and fourth alignment solder bumps 221 are provided on a side of the interconnection device 2 away from the second alignment bonding parts 21. The forming first alignment bonding parts at first target positions on a side of the carrier includes:
forming a metal layer on the side of the carrier;
etching the metal layer, and forming the third alignment bonding pads at the first target positions and the second target positions;
forming the first alignment solder bumps at the first target positions on a side of the third alignment bonding pads away from the carrier.

In this embodiment, in combination with steps (A)-(B) of FIG. 5, a metal layer is formed on one side of the carrier 8 by a plating or deposition process, then the metal layer is etched, patterns of the third alignment bonding pads 14 are formed at the first target positions and the second target positions, then the first alignment solder bumps 11 are formed on the third alignment bonding pads 14 located at the first target positions, and the third alignment bonding pads 14 located at the second target positions are used for aligned connection with the fourth alignment bonding parts 22 (i.e., the fourth alignment solder bumps 221) on the interconnection device 2.

The attaching each respective interconnection device of the interconnection devices to a respective second target position of second target positions of the carrier includes:
aligning and connecting the fourth alignment solder bumps with the third alignment bonding pads at the second target positions by fusion bonding.

As shown in step (C) of FIG. 5, the fourth alignment solder bumps 221 of the interconnection device 2 are directed toward the third alignment bonding pads 14, and the fourth alignment solder bumps 221 and the third alignment bonding pads 14 are in contact with each other without being accurately centered in a direction perpendicular to the plane in which the carrier 8 is located. During the bonding process, the fourth alignment solder bumps 221 are in a molten state or a partially molten state, and at this time, based on the principle of minimum surface energy, the fourth alignment solder bumps 221 in the molten or partially molten state tend to deform and move to bring the fourth alignment solder bumps 221 and the third alignment bonding pads 14 near a centered state, thus the interconnection device 2 is driven to be accurately aligned to the second target position, and the interconnection device 2 is accurately fixed at the second target position after the alignment solder bumps are cooled.

In other embodiments, the first alignment bonding parts 1 may further include only the first alignment solder bumps 11, that is the first alignment solder bumps 11 are formed at the first target positions on one side surface of the carrier 8, and the fifth alignment bonding parts 4 are formed at the second target positions, and the subsequent steps are similar to those of FIGS. 2 to 5, and will not be repeated here.

In some embodiments, as shown in FIGS. 2 to 5, the second alignment bonding parts 21 include second alignment solder bumps 211, and the third alignment bonding parts 31 include first alignment bonding pads 311. The aligning a portion of the third alignment bonding parts with the first alignment bonding parts, and aligning the remaining third alignment bonding parts with the second alignment bonding parts by fusion bonding includes:
aligning and connecting the portion of the first alignment bonding pads with the first alignment solder bumps by fusion bonding, and aligning and connecting the remaining first alignment bonding pads with the second alignment solder bumps.

In this embodiment, the first alignment bonding parts 1 are the alignment solder bumps (i.e., the first alignment solder bumps 11), the second alignment bonding parts 21 are the alignment solder bumps (i.e., the second alignment solder bumps 211), and the third alignment bonding parts 31 are the alignment bonding pads (i.e., the first alignment bonding pads 311). The first alignment bonding pads 311 and the first alignment solder bumps 11 on the carrier 8 are substantially aligned, the remaining first alignment bonding pads 311 and the second alignment solder bumps 211 on the interconnection device 2 are substantially aligned. In the bonding process, the first alignment solder bumps 11 and the second alignment solder bumps 211 are heated to be in a molten state or a partial molten state, the first alignment bonding pads 311 are infiltrated by the alignment solder bumps in the molten state or the partial molten state, the first alignment solder bumps 11 in the molten state or the partial molten state tend to deform and move to bring the first alignment solder bumps 11 and the first alignment bonding pads 311 near a centered state, and the second alignment solder bumps 211 in the molten state or the partial molten state tend to deform and move to bring the second alignment solder bumps 211 and the first alignment bonding pads 311 near a centered state, so that the lighter semiconductor device 3 is driven to be accurately aligned to a target position, the semiconductor device 3 is accurately fixed to the target positions after the alignment solder bumps are cooled, thereby realizing high-strength mechanical fixing (up to kilogram force level) of the semiconductor device 3, solving shifting and rotating of the semiconductor device 3 in the subsequent molding process, and effectively improving the yield of the subsequent process.

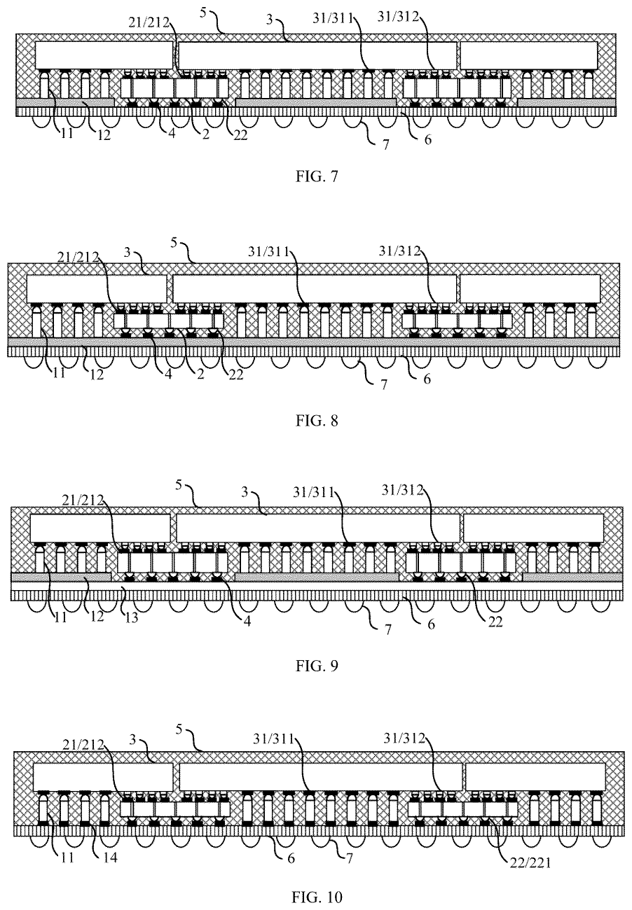

In some embodiments, as shown in FIG. 7 to FIG. 10, the second alignment bonding parts 21 include second alignment bonding pads 212, and the third alignment bonding parts 31 include first alignment bonding pads 311 and third alignment solder bumps 312. The aligning a portion of the third alignment bonding parts with the first alignment bonding parts and aligning the remaining third alignment bonding parts with the second alignment bonding parts by fusion bonding includes:
aligning and connecting the portion of the first alignment bonding pads with the first alignment solder bumps, and aligning and connecting the third alignment solder bumps with the second alignment bonding pads by fusion bonding.

In this embodiment, the first alignment bonding parts 1 are alignment solder bumps (i.e., the first alignment solder bumps 11), the second alignment bonding parts 21 are alignment bonding pads (i.e., the second alignment bonding pads 212), and the third alignment bonding parts 31 include first alignment bonding pads 311 corresponding to the first alignment solder bumps 11 and third alignment solder bumps 312 corresponding to the second alignment bonding pads 212. The first alignment bonding pad 311 are substantially aligned with the first alignment solder bumps 11 on the carrier 8, and the third alignment solder bumps 312 are substantially aligned with the second alignment bonding pad 212 on the interconnection device 2. In the bonding process, the first alignment solder bumps 11 and the third alignment solder bumps 312 are respectively heated to be in a molten state or a partially molten state, based on the minimum surface energy principle, the first alignment solder bumps 11 in the molten state or the partially molten state tend to deform and move to bring the first alignment solder bumps 11 and the first alignment bonding pad 311 near a centered state, and the third alignment solder bumps 312 in the molten state or the partially molten state tends to deform and move to enable the third alignment solder bumps 312 and the second alignment bonding pad 212 near the centered state, thus the lighter semiconductor device 3 is driven to be accurately aligned to a target position, and the semiconductor device 3 is accurately fixed to the target positions after the alignment solder bumps are cooled, thereby realizing high-strength mechanical fixing (up to kilogram force level) of the semiconductor device 3, solving shifting and rotating of the semiconductor device 3 in the subsequent molding process, and effectively improving the yield of the subsequent process.

In some embodiments, as shown in FIG. 6, the first alignment bonding parts 1 include third alignment bonding pads 14, and fourth alignment solder bumps 221 are provided on a side of the interconnection device 2 away from the second alignment bonding parts 21, i.e., the fourth alignment bonding parts 22 are alignment solder bumps. The forming first alignment bonding parts at first target positions on a side of the carrier includes:
forming the third alignment bonding pads at the first target positions and the second target positions on the side of the carrier.

As shown in step (A) of FIG. 6, the third alignment bonding pads 14 are formed on the side of the carrier 8 by using a plating or deposition process, the third alignment bonding pads 14 at the first target positions are used for aligned connection with third alignment bonding parts 31 on the semiconductor device 3, and the third alignment bonding pads 14 at the second target positions are used for aligned connection with fourth alignment bonding parts 22 (i.e., fourth alignment solder bumps 221) on the interconnection device 2.

The attaching each respective interconnection device of the interconnection devices to a respective second target position of second target positions of the carrier includes:
aligning and connecting the fourth alignment solder bumps with the third alignment bonding pad located at the second target positions by fusion bonding.

As shown in step (B) of FIG. 6, the fourth alignment solder bumps 221 of the interconnection device 2 are directed toward the third alignment bonding pads 14, and the fourth alignment solder bumps 221 and the third alignment bonding pads 14 are in contact with each other without being accurately centered in a direction perpendicular to the plane in which the carrier 8 is located. During the bonding process, the fourth alignment solder bumps 221 are in a molten state or a partially molten state, and at this time, based on the principle of minimum surface energy, the fourth alignment solder bumps 221 in the molten or partially molten state tend to deform and move to bring the fourth alignment solder bumps 221 and the third alignment bonding pads 14 near a centered state, thus driving the interconnection device 2 is driven to be accurately aligned to the second target position, the interconnection device 2 is accurately fixed at the second target position after the alignment solder bumps are cooled.

In some embodiments, as shown in FIG. 6, the second alignment bonding parts 21 include second alignment solder bumps 211, and the third alignment bonding parts 31 include fifth alignment solder bumps 313 and first alignment bonding pads 311.

The aligning a portion of the third alignment bonding parts with the first alignment bonding parts and aligning the remaining third alignment bonding parts with the second alignment bonding parts by fusion bonding includes:
aligning and connecting the fifth alignment solder bumps with the third alignment bonding pads, and aligning and connecting the first alignment bonding pads with the second alignment bonding parts bumps by fusion bonding.

In this embodiment, as shown in step (C) of FIG. 6, the first alignment bonding parts 1 located at the first target positions are the alignment bonding pads (i.e., the third alignment bonding pads 14), the second alignment bonding parts 21 are the alignment solder bumps (i.e., the second alignment solder bumps 211), the third alignment bonding parts 31 corresponding to the third alignment bonding pads 14 are the fifth alignment solder bumps 313, and the third alignment bonding parts 31 corresponding to the second alignment solder bumps 211 are the alignment bonding pads (i.e., the first alignment bonding pads 311). The fifth alignment solder bumps 313 are substantially aligned with the third alignment solder bumps 14 on the carrier 8, and the first alignment solder bumps 311 are substantially aligned with the second alignment solder bumps 211 on the interconnection device 2. During the bonding process, the fifth alignment solder bumps 313 and the second alignment solder bumps 211 are heated to be in a molten state or a partial molten state, the alignment solder bumps in the molten state or the partial molten state infiltrate the corresponding alignment solder bumps, based on the minimum surface energy principle, the fifth alignment solder bumps 313 in the molten state or the partial molten state tend to deform and move to bring the fifth alignment solder bump 313 and the third alignment solder bump 14 near a centered state, and the second alignment solder bumps 211 in the molten state or the partial molten state tend to deform and move to bring the second alignment solder bumps 211 and the first alignment solder bumps 311 near the centered state, so that the lighter semiconductor device 3 is driven to be accurately aligned to a target position, and the semiconductor device 3 is accurately fixed to the target position, thereby realizing high-strength mechanical fixing (up to kilogram force level) of the semiconductor device 3, solving shifting and rotating of the semiconductor device 3 in the subsequent molding process, and effectively improving the yield of the subsequent process.

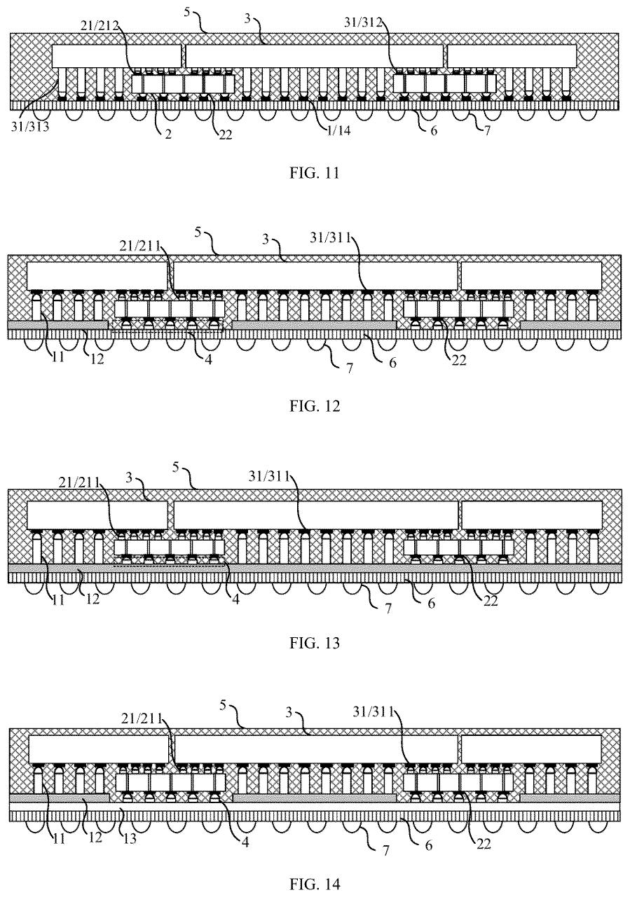

In some embodiments, as shown in FIG. 11, the second alignment bonding parts 21 include second alignment bonding pads 212, and the third alignment bonding parts 31 include third alignment solder bumps 312 and fifth alignment solder bumps 313. The aligning a portion of the third alignment bonding parts with the first alignment bonding parts and aligning the remaining third alignment bonding parts with the second alignment bonding parts by fusion bonding includes:
aligning and connecting the fifth alignment solder bumps with the third alignment bonding pads by fusion bonding, and aligning and connecting the third alignment solder bumps with the second alignment bonding pads.

In this embodiment, the first alignment bonding parts 1 located at the first target positions are the alignment bonding pads (i.e., the third alignment bonding pads 14), the second alignment bonding parts 21 are the alignment bonding pads (i.e., the second alignment bonding pads 212), the third alignment bonding parts 31 corresponding to the third alignment bonding pads 14 are the fifth alignment solder bumps 313, and the third alignment bonding parts 31 corresponding to the second alignment bonding pads 212 are the alignment solder bumps (i.e., the third alignment solder bumps 312). The fifth alignment solder bumps 313 are substantially aligned with the third alignment solder bumps 14 on the carrier 8, and the first alignment solder bumps 311 are substantially aligned with the second alignment solder bumps 211 on the interconnection device 2. During the soldering process, the fifth alignment solder bumps 313 and the third alignment solder bumps 312 are heated to be in a molten state or a partially molten state, the alignment solder bumps in the molten state or the partially molten state infiltrate the corresponding alignment solder bumps, based on the minimum surface energy principle, the fifth alignment solder bumps 313 in the molten state or the partially molten state tend to deform and move to bring the fifth alignment solder bump 313 and the third alignment solder bump 14 near a centered state, and the third alignment solder bump 312 in the molten state or the partially molten state tend to deform and move to bring the third alignment solder bump 312 and the second alignment solder bump 212 near the centered state, so that the lighter semiconductor device 3 is driven to be accurately aligned to a target position, and the semiconductor device 3 is accurately fixed to the target position after the alignment solder bumps are cooled, thereby realizing high-strength mechanical fixing (up to kilogram force level) of the semiconductor device 3, solving shifting and rotating of the semiconductor device 3 in the subsequent molding process, and effectively improving the yield of the subsequent process.

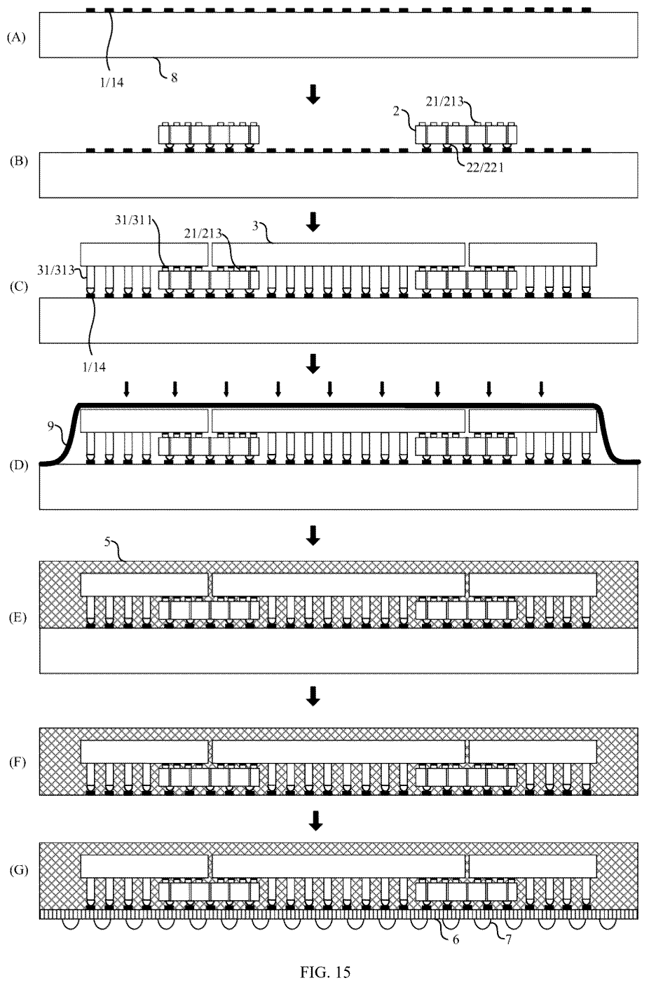

In some embodiments, as shown in FIG. 15, the second alignment bonding parts 21 include thermo-compression bonding pads 213 having a solder mask, and the third alignment bonding parts 31 include fifth alignment solder bumps 313 and first alignment bonding pads 311. The aligning a portion of the third alignment bonding parts with the first alignment bonding parts and aligning the remaining third alignment bonding parts with the second alignment bonding parts by fusion bonding includes:
aligning and connecting the fifth alignment solder bumps with the third aligning bonding pads by fusion bonding.

The first alignment bonding pads are aligned respectively with the thermo-compression bonding pads by thermo-compression bonding.

In this embodiment, the thermo-compression bonding pads 213 are located at the side of the interconnection device 2 away from the carrier 8, and a solder mask is coated on a side surface of the thermo-compression bonding pads 213 away from the interconnection device 2. Compared with the alignment solder bumps described above, the thermo-compression bonding pads 213 have less solder material, no bump structure is formed, the thickness of the interconnection device 2 is thinner, smaller-sized spacing and diameter can be realized, and a high-density and thinner packaging structure is facilitated. Although the solder mask on the thermo-compression bonding pad 213 has no bumps, it has a certain auto-alignment function.

As shown in step (C) of FIG. 15, the first alignment bonding parts 1 located at the first target positions are the alignment bonding pads (i.e., the third alignment bonding pads 14), the second alignment bonding parts 21 are the thermo-compression bonding pads 213, the third alignment bonding parts 31 corresponding to the third alignment bonding pads 14 are the fifth alignment solder bumps 313, and the third alignment bonding parts 31 corresponding to the thermo-compression bonding pads 213 are alignment bonding pads (i.e., the first alignment bonding pads 311). The fifth alignment solder bumps 313 are substantially aligned with the third alignment bonding pads 14 on the carrier 8, the first alignment solder bumps 311 are substantially aligned with the thermo-compression bonding pads 213 on the interconnection device 2. During the bonding process, the fifth alignment solder bumps 313 are in a molten state or a partial molten state, the alignment solder bumps in the molten state or the partial molten state infiltrate the alignment bonding pads corresponding to the fifth alignment solder bumps, based on the minimum surface energy principle, the fifth alignment solder bumps 313 in the molten state or the partial molten state tend to deform and move to bring the fifth alignment solder bumps 313 and the third alignment bonding pads 14 near a centered state, the surface tension generated by the fifth alignment solder bumps 313 can drive the lighter semiconductor device 3 to be accurately aligned to a target position, and the semiconductor device 3 is accurately fixed at the target position after the alignment solder bumps 313 are cooled, thereby realizing high-strength mechanical fixing (up to kilogram force level) of the semiconductor device 3, solving shifting and rotating of the semiconductor device 3 in the subsequent molding process, and effectively improving the yield of the subsequent process.

The thermo-compression bonding pads 213 and the first alignment bonding pads 311 are in contact with each other at this time, but no realized a fixed connection relationship. As shown in step (D) of FIG. 15, the thermo-compression bonding pads 213 are heated, so that the solder mask on the thermo-compression bonding pad 213 is in a molten state, a downward pressure is applied from above the semiconductor device 3 (i.e., the side away from the first alignment bonding pads 311), and then cooling is performed and the downward pressure is maintained, thus the solder mask on the thermos-compression bonding pads 213 is solidified, thereby realizing an alignment connection of the thermo-compression bonding pads 213 and the first alignment bonding pads 311. The temperature at the time of thermo-compression bonding is lower than the temperature at the time of fusion bonding.

In some embodiments, a flat plate is placed on a side of the semiconductor device 3 away from the third alignment bonding parts 31, and the flattening process is performed by pressing the flat plate downward, so that the side surfaces of all the semiconductor devices 3 away from the third alignment bonding parts 31 are located at the same height.

In some embodiments, as shown in FIG. 15, the packaging structure obtained in the step (C) is placed in an autoclave 9, and the packaging structure is covered with a thermo-compression film to form a confined space, and a uniform pressure is applied to the semiconductor devices 3 by a vacuum pumping manner, so that the side surfaces of different semiconductor devices 3 away from the third alignment bonding parts 31 do not need to be located at the same height, and damage to the packaging structure caused by excessive pressure is avoided.

It should be noted that, the second alignment bonding parts 21 are configured as a thermo-compression bonding pad 213 with a solder mask, and the aligned connection between the thermo-compression bonding pads 213 and the first alignment bonding pads 311 is achieved by a thermo-compression process, which may be applied to all embodiments provided in the present disclosure, which is not repeated herein, so as to avoid repetitive description.

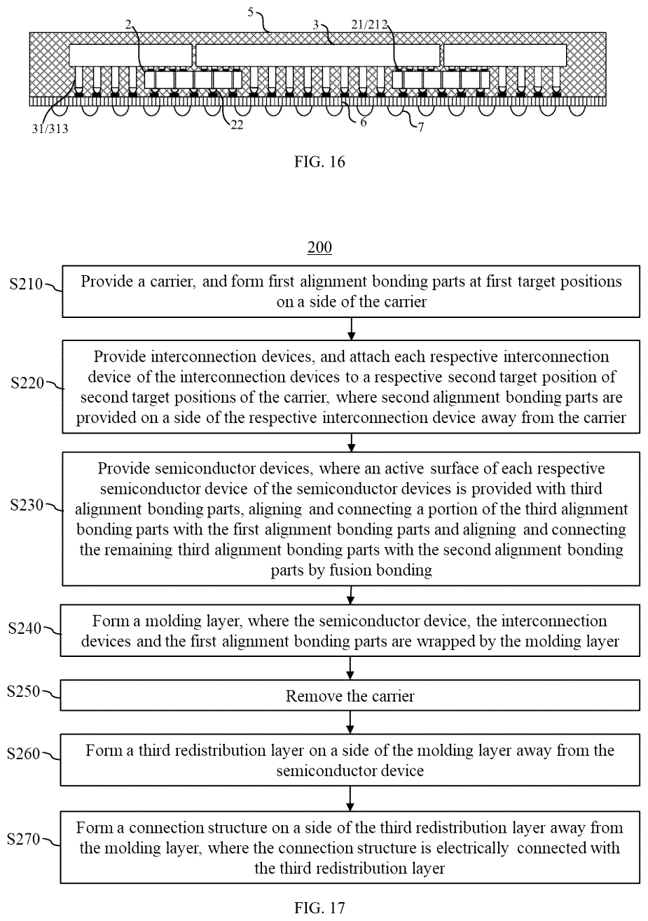

In some embodiments, as shown in FIG. 16, the second alignment bonding parts 21 include second alignment bonding pads 212, and the third alignment bonding parts 31 corresponding to the second alignment bonding pads 212 are thermo-compression bonding pads having a solder mask. The specific fabricating steps are similar to those shown in FIG. 15, and will not be repeated again herein.

In some embodiments, as shown in FIG. 17, the semiconductor packaging method 200 includes steps S210, S220, and S230, which are similar to steps S110 to S130, and further includes steps S240, S250, S260, and S270, which are described in further details below.

At S240, a molding layer is formed, where the semiconductor device, the interconnection devices and the first alignment bonding parts are wrapped by the molding layer.

After the third alignment bonding parts 31 are aligned with the first alignment bonding parts 1 and the third alignment bonding parts 21, as shown in FIGS. 2 to 5, the molding process such as injection molding, compression molding or printing may be used for molding, and the material for preparing the molding layer 5 includes a molding compound of a resin material (for example, epoxy resin). The molding layer 5 and the semiconductor devices 3 are located on the same side of the carrier 8, and the molding layer 5 covers the passive surface of the semiconductor device 3, also wraps the side surface of the semiconductor device 3, and fills the gaps among the semiconductor devices 3, the interconnection devices 2 and the first alignment bonding parts 1.

At S250, the carrier is removed.

In this step, the carrier 8 is removed by one of thermal debonding, laser debonding, and mechanical debonding. The manner of removing the carrier may be selected according to the type of the carrier 8. If the carrier 8 is a glass carrier or other light-transmitting carriers, any one of thermal debonding, mechanical debonding and laser debonding breaking modes can be adopted to remove the carrier 8. If the carrier 8 is a stainless steel carrier or other opaque carrier, a thermal debonding or mechanical debonding is used to remove the carrier. As shown in FIG. 2, after the carrier 8 is removed, the first redistribution layer 12 and the fifth alignment bonding parts are exposed. As shown in FIG. 3, after the carrier 8 is removed, the first redistribution layer 12 is exposed. As shown in FIG. 4, after the carrier 8 is removed, the second redistribution layer 13 is exposed. As shown in FIG. 5 or 13, after the carrier 8 is removed, the third alignment bonding pads 14 are exposed.

At S260, a third redistribution layer is formed on a side of the molding layer away from the semiconductor device.

In this step, the third redistribution layer 6 may be prepared by using processes known to those skilled in art, and will not be described herein. The third redistribution layer 6 includes at least one metal layer and at least one insulator layer. The redistribution layer has higher routing density, so that the routing density on the external circuit board is reduced, the redistribution difficulty is reduced, and the cost is reduced.

It should be noted that the number of metal layers in the third redistribution layer 6 may be equal to or different from the number of metal layers in the first redistribution layer 12 and the second redistribution layer 13.

At S270, a connection structure is formed on a side of the third redistribution layer away from the molding layer, where the connection structure is electrically connected with the third redistribution layer.

In this embodiment, the connection structure 7 is used for connecting external devices, and the number and distribution of the connection structures 7 can be set according to the external devices. External devices are all devices known to those skilled in art, such as Printed Circuit Boards (PCBs) or processors.

In some embodiments, as shown in FIG. 2 to FIG. 16, the connection structure 7 includes solder balls electrically connected with the third redistribution layer 6, the third redistribution layer 6 is electrically connected with the first alignment bonding parts 1, and the first alignment bonding parts 1 are electrically connected with the semiconductor device 3, thus realizing the electrical connection of the semiconductor device 3 to an external device.

It should be noted that FIG. 2 to FIG. 16 only exemplarily illustrate that the connection structure 6 is arranged in a spherical shape, but do not constitute a limitation of the semiconductor packaging method provided in the embodiment of the present disclosure. In other embodiments, the connection structure 7 may be arranged in other forms, such as a column or a block, which is not limited herein.

Steps S210 to S230 are similar to steps S110 to S130, and the explanation of steps S110 to S130 will be referred to herein and will not be repeated.

In some embodiments, as shown in FIG. 2 to FIG. 14, the interconnection device 2 further includes a through hole extending through the interconnection device body, and the second alignment bonding parts 21 is connected with the fourth alignment bonding parts 22 via the through hole. The semiconductor device 3 can be further connected to the outside through the third alignment bonding parts 31, the second alignment bonding parts 21, the through hole, the fourth alignment bonding parts and the fifth alignment bonding parts, so that the through wire density of the semiconductor device 3 is improved.

On the basis of the foregoing embodiments, the embodiments of the present disclosure further provide a semiconductor component, where the semiconductor component is packaged by any one of the foregoing semiconductor packaging methods, and has corresponding beneficial effects, which is not repeated herein, so as to avoid repetitive description.

On the basis of the foregoing implementation manner, the embodiment of the present disclosure further provides an electronic device, which includes the semiconductor component and has corresponding beneficial effects, which is not repeated herein, so as to avoid repetitive description.

It should be noted that in this document, relational terms such as “first” and “second” and the like are used solely to distinguish one entity or action from another entity or action without necessarily requiring or implying any actual such relationship or order between such entities or actions. Moreover, the terms “comprise,” “include,” or any other variation thereof, are intended to cover a non-exclusive inclusion, such that a process, method, material, or equipment that comprises a list of elements does not include only those elements but may include other elements not expressly listed or inherent to such process, method, material, or equipment. Without further limitation, an element defined by the phrase “include one . . . ” does not exclude the presence of other like elements in a process, method, material, or equipment that includes the element.

The foregoing is merely a specific embodiment of the present disclosure to enable one skilled in art to understand or practice the present disclosure. Various modifications to these embodiments will be readily obvious to those skilled in art, and the generic principles defined herein may be applied to other embodiments without departing from the spirit or scope of the present disclosure. Thus, the present disclosure is not intended to be limited to the embodiments shown and described herein but is to be accorded with the widest scope consistent with the principles and novel features disclosed herein.

What is claimed is:

1. A semiconductor packaging method, comprising:
providing a carrier, and forming first alignment bonding parts respectively at first target positions on a side of the carrier;
providing interconnection devices and attaching the interconnection devices to respective second target positions on the side of the carrier, wherein each of the interconnection devices has second alignment bonding parts formed on a side of the interconnection device facing away from the carrier; and
providing semiconductor devices, wherein each of the semiconductor devices has third alignment bonding parts formed on an active surface thereof, the third alignment bonding parts including a first portion corresponding, respectively, to a respective portion of the first alignment bonding parts, and a second portion corresponding, respectively to a respective portion of the second alignment bonding parts on a respective interconnection device;
mounting the semiconductor devices on the side of the carrier over the first alignment bonding parts and the interconnect devices, including, for each respective semiconductor device, aligning and connecting the first portion of the third alignment bonding parts of the respective semiconductor device with corresponding first alignment bonding parts by fusion bonding, and aligning and connecting the second portion of the third alignment bonding parts of the respective semiconductor device with corresponding second alignment bonding parts on a respective interconnect device;
wherein each of the first alignment bonding parts, the second alignment bonding parts and the third alignment bonding parts includes an alignment solder bump or alignment bonding pad, and wherein mounting the semiconductor devices on the side of the carrier includes aligning and connecting solder bumps on one of the respective semiconductor device and the carrier with solder pads on the other one of the respective semiconductor device and the carrier, and aligning and connecting solder bumps on one of the respective semiconductor device and the respective interconnect device with solder pads on the other one of the respective semiconductor device and the respective interconnect device.

2. The semiconductor packaging method according to claim 1, wherein mounting the semiconductor devices on the side of the carrier over the first alignment bonding parts and the interconnect devices includes:
heating the alignment solder bumps, so that the alignment solder bumps are at least partially in a molten state; and
bonding the alignment solder bumps at least partially in the molten state with the first alignment bonding pads.

3. The semiconductor packaging method according to claim 1, wherein the first alignment bonding parts include first alignment solder bumps formed on a first redistribution layer, and each of the interconnection devices further includes fourth alignment bonding parts formed on a side thereof away from the second alignment bonding parts, and wherein:
forming the first alignment bonding parts at the first target positions on the side of the carrier includes:
forming the first redistribution layer on the side of the carrier;
forming the first alignment solder bumps at the first target positions on a side of the first redistribution layer away from the carrier; and
attaching the interconnection devices to respective second target positions on the side of the carrier includes:
etching the first redistribution layer to form openings at the second target positions, wherein areas of the side of the carrier are exposed by the openings;
forming the fifth alignment bonding parts in the areas on the side of the carrier exposed by the openings; and
aligning and connecting the fifth alignment bonding parts respectively with the fourth alignment bonding parts by fusion bonding, including aligning and connecting solder bumps on one of the respective interconnect device and the carrier with alignment bonding parts on the other one of the respective interconnect device and the carrier.

4. The semiconductor packaging method according to claim 1, wherein the first alignment bonding parts include first alignment solder bumps formed on a first redistribution layer, and each of the interconnection devices further includes fourth alignment bonding parts formed on a side thereof away from the second alignment bonding parts, and wherein:
forming the first alignment bonding parts at the first target positions on the side of the carrier includes:
forming the first redistribution layer on the side of the carrier; and
forming the first alignment solder bumps at the first target positions on a side of the first redistribution layer away from the carrier; and
attaching the interconnection devices to respective second target positions on the side of the carrier includes:
forming fifth alignment bonding parts at the second target positions on the side of the first redistribution layer away from the carrier; and
aligning and connecting the fifth alignment bonding parts respectively with the fourth alignment bonding parts by fusion bonding, including aligning and connecting solder bumps on one of the respective interconnect device and the carrier with alignment bonding parts on the other one of the respective interconnect device and the carrier.

5. The semiconductor packaging method according to claim 1, wherein the first alignment bonding parts include first alignment solder bumps formed on a first redistribution layer and a second redistribution layer, and each of the interconnection devices further includes fourth alignment bonding parts formed on a side thereof away from the second alignment bonding parts, and wherein:
forming the first alignment bonding parts at the first target positions on the side of the carrier includes:
forming the second redistribution layer on the side of the carrier;
forming the first redistribution layer on a side of the second redistribution layer away from the carrier; and
forming the first alignment solder bumps at the first target positions on a side of the first redistribution layer away from the second redistribution layer; and
attaching the interconnection devices to respective second target positions on the side of the carrier includes:
etching the first redistribution layer to form openings at the second target positions, wherein areas of the second redistribution layer are exposed by the openings;
forming fifth alignment bonding parts on the second redistribution layer in the areas exposed by the openings; and
aligning and connecting the fifth alignment bonding parts respectively with the fourth alignment bonding parts by fusion bonding, including aligning and connecting solder bumps on one of the respective interconnect device and the second redistribution layer with alignment bonding parts on the other one of the respective interconnect device and the second redistribution layer.

6. The semiconductor packaging method according to claim 1, wherein the first alignment bonding parts include first alignment solder bumps and third alignment bonding pads, and each of the interconnection devices further includes fourth alignment bonding parts formed on a side thereof away from the second alignment bonding parts, and wherein:
forming the first alignment bonding parts at the first target positions on the side of the carrier includes:
forming a metal layer on the side of the carrier;
etching away portions of the metal layer to form the third alignment bonding pads at the first target positions and the second target positions; and
forming first alignment solder bumps at the first target positions, each of the first alignment solder bumps being formed on a side of a corresponding one of the third alignment bonding pads away from the carrier;
attaching the interconnection devices to respective second target positions on the side of the carrier includes:
aligning and connecting the fourth alignment solder bumps of each interconnect device respectively with corresponding ones of the third alignment bonding pads by fusion bonding.

7. The semiconductor packaging method of claim 3, wherein the second alignment bonding parts include second alignment solder bumps, and the third alignment bonding parts include first alignment bonding pads;
aligning the portion of the third alignment bonding parts with the first alignment bonding parts and aligning the remaining third alignment bonding parts with the second alignment bonding parts by fusion bonding includes:
aligning and connecting a portion of the first alignment bonding pads with the first alignment solder bumps by fusion bonding, and aligning and connecting the remaining first alignment bonding pads with the second alignment solder bumps.

8. The semiconductor packaging method of claim 3, wherein the second alignment bonding parts include second alignment bonding pads, and the third alignment bonding parts include first alignment bonding pads and third alignment solder bumps;
aligning the portion of the third alignment bonding parts with the first alignment bonding parts and aligning the remaining third alignment bonding parts with the second alignment bonding parts by fusion bonding includes:
aligning and connecting a portion of the first alignment bonding pads with the first alignment solder bumps and aligning and connecting the third alignment solder bumps with the second alignment bonding pads by fusion bonding.

9. The semiconductor packaging method according to claim 1, wherein the first alignment bonding parts include third alignment bonding pads, and fourth alignment solder bumps are provided on a side of the respective interconnection device away from the second alignment bonding parts;
forming the first alignment bonding parts at the first target positions on the side of the carrier includes:
forming the third alignment bonding pads at the first target positions and the second target positions on the side of the carrier;
attaching each respective interconnection device of the interconnection devices to a respective second target position of the second target positions of the carrier includes:
aligning and connecting the fourth alignment solder bumps with the third alignment bonding pads located at the second target positions by fusion bonding.

10. The semiconductor packaging method according to claim 9, wherein the second alignment bonding parts include second alignment bonding pads, and the third alignment bonding parts include third alignment solder bumps and fifth alignment solder bumps;
aligning a portion of the third alignment bonding parts with the first alignment bonding parts and aligning the remaining third alignment bonding parts with the second alignment bonding parts by fusion bonding, comprising:
aligning and connecting the fifth alignment solder bumps with the third alignment bonding pads, and aligning and connecting the third alignment solder bumps with the second alignment bonding pads by fusion bonding.

11. The semiconductor packaging method according to claim 9, wherein the second alignment bonding parts include second alignment solder bumps, and the third alignment bonding parts include a fifth alignment solder bumps and first alignment bonding pads;
aligning the portion of the third alignment bonding parts with the first alignment bonding parts and aligning the remaining third alignment bonding parts with the second alignment bonding parts by fusion bonding includes:
aligning and connecting the fifth alignment solder bumps with the third alignment bonding pads, and aligning and connecting the first alignment bonding pads with the second alignment solder bumps by fusion bonding.

12. The semiconductor packaging method according to claim 9, wherein the second alignment bonding parts includes thermo-compression bonding pads having a solder mask, and the third alignment bonding parts include third alignment solder bumps and first alignment bonding pads;
aligning the portion of the third alignment bonding parts with the first alignment bonding parts and aligning the remaining third alignment bonding parts with the second alignment bonding parts by fusion bonding includes:
aligning and connecting the fifth alignment solder bumps with the third alignment bonding pads by fusion bonding; and
aligning and connecting the first alignment bonding pads and the thermo-compression bonding pads by thermo-compression bonding.

13. The semiconductor packaging method according to claim 1, further comprising:
forming a molding layer, wherein the semiconductor devices, the interconnection devices and the first alignment bonding parts are wrapped by the molding layer;
removing the carrier;
forming a third redistribution layer on a side of the molding layer away from the semiconductor device; and
forming a connection structure on a side of the third redistribution layer away from the molding layer, wherein the connection structure is electrically connected with the third redistribution layer.

14. The semiconductor packaging method according to claim 4, wherein the second alignment bonding parts include second alignment solder bumps, and the third alignment bonding parts include first alignment bonding pads;
aligning the portion of the third alignment bonding parts with the first alignment bonding parts and aligning the remaining third alignment bonding parts with the second alignment bonding parts by fusion bonding includes:
aligning and connecting a portion of the first alignment bonding pads with the first alignment solder bumps by fusion bonding, and aligning and connecting the remaining first alignment bonding pads with the second alignment solder bumps.

15. The semiconductor packaging method according to claim 5, wherein the second alignment bonding parts include second alignment solder bumps, and the third alignment bonding parts include first alignment bonding pads;
aligning the portion of the third alignment bonding parts with the first alignment bonding parts and aligning the remaining third alignment bonding parts with the second alignment bonding parts by fusion bonding includes:
aligning and connecting a portion of the first alignment bonding pads with the first alignment solder bumps by fusion bonding, and aligning and connecting the remaining first alignment bonding pads with the second alignment solder bumps.

16. The semiconductor packaging method according to claim 6, wherein the second alignment bonding parts include second alignment solder bumps, and the third alignment bonding parts include first alignment bonding pads;
aligning the portion of the third alignment bonding parts with the first alignment bonding parts and aligning the remaining third alignment bonding parts with the second alignment bonding parts by fusion bonding includes:
aligning and connecting a portion of the first alignment bonding pads with the first alignment solder bumps by fusion bonding, and aligning and connecting the remaining first alignment bonding pads with the second alignment solder bumps.

17. The semiconductor packaging method according to claim 4, wherein the second alignment bonding parts include second alignment bonding pads, and the third alignment bonding parts include first alignment bonding pads and third alignment solder bumps;
aligning the portion of the third alignment bonding parts with the first alignment bonding parts and aligning the remaining third alignment bonding parts with the second alignment bonding parts by fusion bonding includes:
aligning and connecting a portion of the first alignment bonding pads with the first alignment solder bumps and aligning and connecting the third alignment solder bumps with the second alignment bonding pads by fusion bonding.

18. The semiconductor packaging method according to claim 5, wherein the second alignment bonding parts include second alignment bonding pads, and the third alignment bonding parts include first alignment bonding pads and third alignment solder bumps;
aligning the portion of the third alignment bonding parts with the first alignment bonding parts and aligning the remaining third alignment bonding parts with the second alignment bonding parts by fusion bonding includes:
aligning and connecting a portion of the first alignment bonding pads with the first alignment solder bumps and aligning and connecting the third alignment solder bumps with the second alignment bonding pads by fusion bonding.

19. A semiconductor component, wherein the semiconductor component is packaged based on the semiconductor packaging method according to claim 1.

20. An electronic device, comprising: the semiconductor component according to claim 19.
